(19) United States
(12) Patent Application Publication
(10) Pub. No.: US 2009/0218203 A1
(43) Pub. Date: Sep. 3, 2009

(54) Keypad Shield

(76) Inventor: Alistair Taverner, Essex (GB)

Correspondence Address: ANDRUS, SCEALES, STARKE & SAWALL, LLP, 100 EAST WISCONSIN AVENUE, SUITE 1100, MILWAUKEE, WI, 53202, US

(21) Appl. No.: 11/913,757

(22) PCT Filed: May 8, 2006
(86) PCT No.: PCT/GB06/50093

§ 371 Date: Jul. 2, 2008

(30) Foreign Application Priority Data
May 6, 2005 (GB) 0509278.8
Sep. 5, 2005 (GB) 0518005.4

(51) Int. Cl. H01H 9/02; H03M 11/02

(52) U.S. Cl. 200/304; 341/22

(57) ABSTRACT

The present invention provides a shield for overlying a keypad and restricting the view of third parties. The shield comprises a main body connectable to the keypad and a screen defined in the main body and overlying the keypad. The keypad may only be viewed through the screen by the user of the keypad. The screen may be slidable and may be provided with a film that restricts the viewing angle such that the keypad may only be viewed through the screen from within a range of angles, which range is approximately 20° centered normal to the surface of the screen. The main body further provides an opening through which manual access to the keypad is permitted. The present invention finds particular use on the keypad of ATMs and point of sale PIN units.

This invention relates to a shield mountable on or around a keypad, and in particular a shield that restricts the view of those other than the person using the keypad.

PINs (personal identification numbers) and other alphanumeric codes are required in every day life to verify that a person using a bankcard to withdraw cash from an ATM or pay for goods electronically using the so-called ‘chip and pin’ machines, is authorised to do so. If the person in possession of the card is unaware of the corresponding PIN, the card will not be accepted to withdraw money or pay for goods electronically. Stolen bankcards have always been a common form of fraud, particularly when the only required form of authorisation was a signature, which is easily forged. Now such verification methods are being phased out, criminals now need to ascertain the PIN before stealing or copying the bankcard. This may be carried out by placing a small camera in a discreet location in or around an ATM, and recording all use of the keypad, which inevitably captures footage of the PIN being entered. It may also be achieved by a bystander watching and memorising the entry of the PIN. Then all the observer has to do is steal the card and use the observed PIN. The problem of viewing by bystanders is particularly acute with the design of most chip and pin units which provide limited if any shielding from onlookers, who are usually arranged all around.

It is a principle aim of the present invention to provide a shield mountable on or around existing keypads, to prevent onlookers from viewing the entry of a secret PIN, password or code. Whilst most current use is envisaged for ATMs and point of sale PIN units, the present invention provides a device suitable for any keypad where secret codes are entered.

According to the present invention, there is provided a shield for overlying a keypad and comprising a main body connectable to the keypad, a screen defined in the main body and overlying the keypad, through which screen the keypad may only be viewed by the user of the keypad, the main body further defining an opening through which manual access to the keypad is permitted.

Viewing by the person using the keypad may preferably be only from within a relatively narrow range of angles. The range of angles within which the keypad can be viewed is preferably approximately 20° centred normal to the surface of the keypad in at least one plane. If the angle is centred relative to only one plane, which might often be than running vertically top a bottom of the keypad, a V-shaped viewing range is created that limits view from the sides, but not from in front or behind. Preferably, therefore the viewing range is limited to approximately 20° centred normal to the surface of the keypad in at least a second plane. If this second plane is, as is preferred, normal to the first plane, they together define a pyramidal viewing range having sides angled at 10° normal to the surface of the keypad. Optimally the viewing range is limited in respect to all planes normal to the surface of the keypad, which creates conical viewing range. The screen appears obscured or opaque, when viewed at angles outside the defined viewing range, but the keys may be seen and operated when viewed from within that range.

The main body may include two opposing sidewalls spaced apart laterally, between the upper parts of which extends the screen. The distance between the opposing sidewalls is greater than the respective distance across the keypad so that a user's hand may fit therebetween to operate the keypad. The main body can further include an upper wall or distal wall extending between the two sidewalls. The screen can be defined within the upper wall at a location overlying the keypad such that a user may view the keypad therethrough. In this arrangement the screen and main body are essentially fixed, although it is possible that the shield could be mounted in such away as to be repositioned as a whole. However, to facilitate use by those who are either unable or unwilling to make use of the advantages of the present invention, it is possible for the screen to be mounted in such away as to be moveable relative to the base so as selectively to cover and uncover the keypad. To achieve this, the screen may be slidably located in guide members formed on the upper edge of each sidewall, so that the screen can be slid between a use position, whereat it overlies the keypad, and a retracted position, not overlying the keypad. This arrangement gives a user the option of viewing the keypad directly or through the screen.

A portion of the main body, often a lower portion of each sidewall, is suitably configured to interface with the surface surrounding the keypad. Such an arrangement could include an integrally moulded flange extending outwardly from the lower edge of the main body and in a plane parallel to the surface with which it is to interface. The flange or flanges are suitably sized to facilitate secure fastening of the shield to the keypad, or the structure in which the keypad is mounted. Suitable means of fastening the shield to a keypad could include mechanical fasteners or adhesives. The shield could also be integrally formed with the keypad or the unit in which the keypad is located.

The main components, i.e. the screen and main body are preferably made from plastics material. The screen is preferably made from plastics material that is suitably translucent or clear. The guide members may have a reduced coefficient of friction permitting the screen to slide with reduced resistance, though means to hold the sliding screen in the fully open or closed positions may preferably be provided. High oil based plastics may be used for all main components, as these are less prone to vandalism since chewing gum will not adhere to the surface and glues and inks will not set or dry.

According to the present invention there is also provided a device incorporating a keypad and shield as described above.

In order that it may be better understood, but by way of example only, three embodiments of the present invention will now be described in detail, reference being made to the accompanying drawings in which:

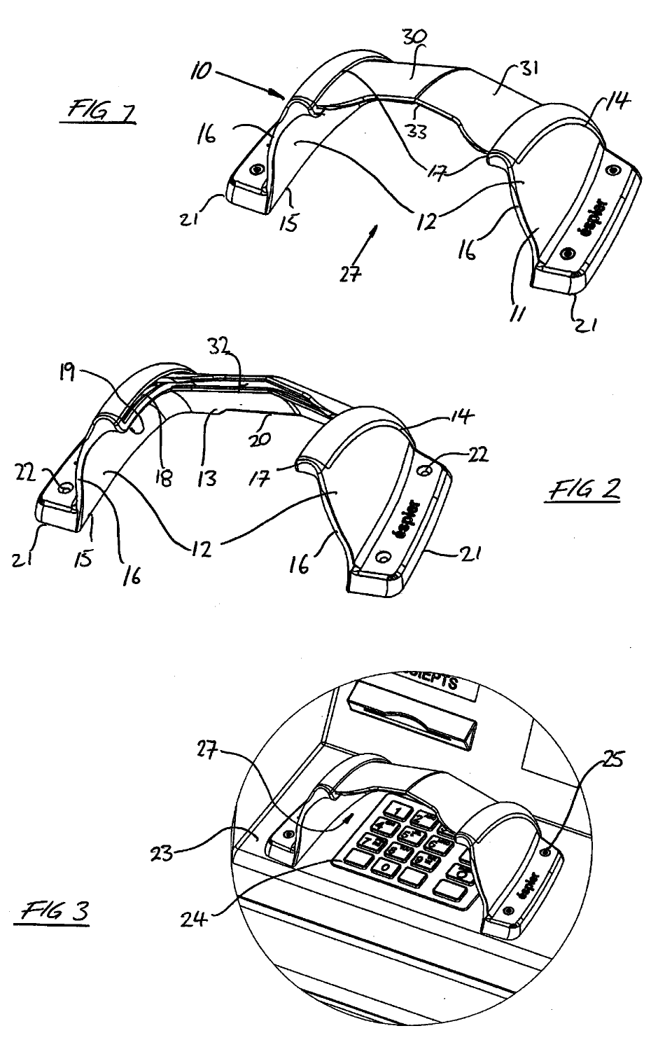

FIG. 1 is a perspective view of a first embodiment of the present invention with a moveable screen shown in the use position;

FIG. 2 is a view corresponding to FIG. 1, but with the screen in the retracted position;

FIG. 3 is a perspective view of the first embodiment of the shield mounted on an ATM;

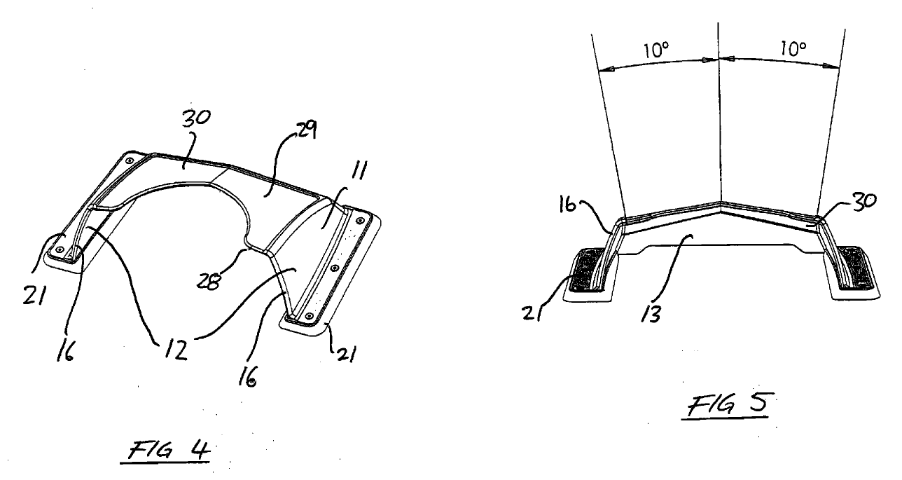

FIG. 4 is a perspective view of a second embodiment of the present invention, where the screen is rigidly fixed to the main body;

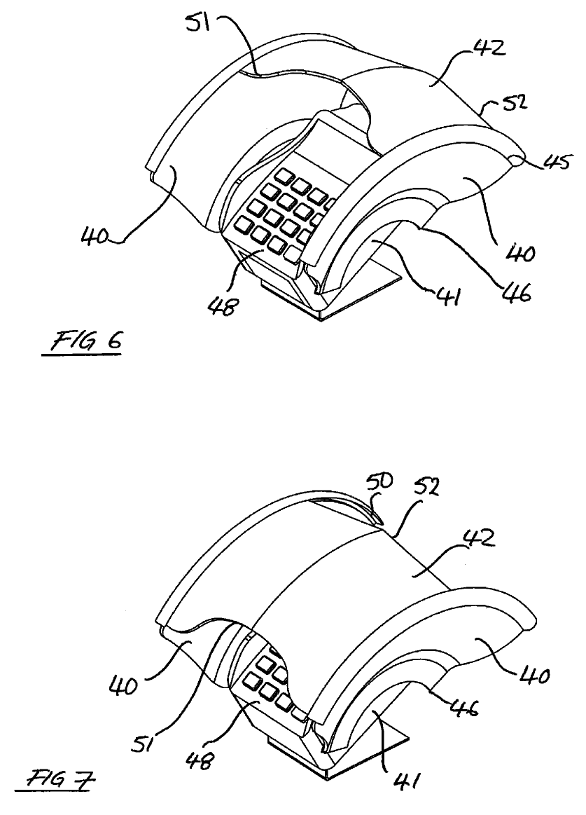

FIG. 5 is a front view of the second embodiment of the present invention;

FIG. 6 is a perspective view of a third embodiment of the present invention, where the shield is mounted to a chip and pin unit; and

FIG. 7 is a view corresponding to FIG. 6, but with the screen in a retracted position.

Referring now to FIGS. 1 to 3, the first embodiment of the shield (generally indicated 10) comprises an integrally moulded main body 11 having two opposing sidewalls 12 and a distal wall 13 extending therebetween. Each sidewall 12 is quadrant shaped, and includes a curved edge 14 and a first and second straight edge 15, 16 meeting at approximately 90°. Each first edge 15 is parallel to the plane of the surface to which the shield 10 is to be mounted, and each second straight edge 16 extends substantially upwardly and faces toward the operator of the keypad. An in-turned lip 17 is defined along the curved edges 14 of each sidewall.

The distal wall 13 extends only partway along the curved edge 14 of each sidewall 12 and has a curvature equal thereto. The distal wall joins each sidewall a set distance below each in-turned lip 17, thus defining an inwardly facing channel 18 therebetween. The width of the channel being equal to said set distance. The distal wall only extends partially up the curved edges of the sidewalls thus defining an open region between the sidewalls near the proximal sides 16. However, the channels 18 extend all the way along the curved edge of each sidewall between the in-turned lips 17 and lower lips 19. A ridge is formed on the distal wall 13 and is centred between the sidewalls 12 and curves from its front edge 20 towards the proximal side of the shield. The distal wall and sidewalls, including the lips and channels are formed from sufficiently opaque material, through which the view of the keypad is obscured. Spark finished plastics material is suitable.

The front edge 20 of the distal wall 13 is coplanar with the base edges 15 of the sidewalls 12. These together provide a stable U-shaped base to support the shield. A flange 21 is provided at the bottom of each sidewall and extends perpendicular and outward therefrom. Two countersunk bores 22 are formed through each flange 21 to enable (as shown in FIG. 3) the shield 10 to be securely fastened to the surface 23 surrounding the keypad 24. Tamper proof bolts 25 having an irregular shaped head are available to securely fasten the main body to the surface 23. The tooling for installing any range of bolts is unique to the irregular shaped head, and not available off the shelf. Alternatively, the main body can be adhered to a suitable surface, for example by applying double-sided tape to the underside of each flange 21. 3M produce a suitable VHB (very high bond) tape made from conformable acrylic foam.

A sliding screen 30 has an upper surface 31, an underside 32, proximal edge 33, a distal edge (not visible) and two opposing side edges (not visible). The two side edges of the screen 30 are slidably located in the channels 18, such that the screen is slidably moveable between a use position (FIG. 1), whereat it is disposed over the keypad to obscure the keys when viewed from outside a defined range, to a retracted position whereat it is overlies the distal wall 13 (FIG. 2). To permit such movement, the profile of the screen 30 must be substantially congruent with the cover portion 13. The width of the screen must be no greater than the distance between the sidewalls and no less than the distance between the in-turned lips. Further the thickness of the screen (defined by the distance between the upper surface and the underside) must be less than the width of the channel 18. The screen 30 is made such that it appears transparent when viewed from within an angle of approximately 20° centred normal to a first and second plane which are themselves normal to the surface of the keypad and to each other. Any part of the screen appears transparent, thus showing the keypad beneath when viewed from within a range defined by the angle to the two planes discussed above. This effectively creates a viewing range with the shape of an inverted square pyramid, having opposing sides arranged at 20° to one another. The screen is made from clear plastic material to which is applied two identical films, whereby the second film overlies the first film and is orientated at 90° thereto. Each film is able to restrict the passage of light that is incident thereon at an angle greater than the desired amount (usually 10° to the normal) with respect to one axis. This defines a V-shaped viewing trench along the respective axis. The second film is overlaid with its axis at 90° to that of the first film. This defines a viewing range that is the result of the two V-shape trenches, being super-imposed on one another at right angles. This creates the inverted square pyramid shape mentioned above.

Thus, when the screen is in the use position, the keypad can be viewed only from a position within a 20° pyramid directly above the screen, preventing onlookers from seeing from a wider angle the keys being pressed. The screen appears obscured when viewed from angles outside that range. Retraction of the screen permits the keypad to be operated without viewing through the screen. This may be desirable for those of impaired movement or eyesight. This reduces the security provided, but it is still better than when no shield is used, because the sidewalls and distal wall obscure the view to some extent.

The proximal end of each channel 18 is closed to constrain the movement of the screen. The other end of each channel at the bottom edge of the cover portion is left open to facilitate insertion of the screen during manufacture. Once the shield 10 is securely mounted to the ATM, the screen is fully constrained within the channels.

The main body comprising the sidewalls and distal wall are made from ABS polycarbonate plastic, which is then spark finished. The spark finish provides a cloudy, obscured effect, preventing the keypad operator's PIN from being seen or recorded through these components, while having a high degree of translucency. Since the main body is translucent, cameras or other illegal prying devices mounted inside the shield to secretly record entry of the PIN are easily noticed. Further, the material is highly lubricious to reduce friction between the channels and the screen and prevent adhesive and chewing gum from sticking to the surface.

The screen 30 is formed from a clear plastics material. As discussed above two films demonstrating the required optical properties (such as that sold by Glass Film Enterprises, Inc. as Lumisty) are adhered to the screen, usually on the underside.

In use, the main body is fastened or adhered to an upper surface 23 surrounding the keypad 24, and the screen 30 is slidably disposed thereover. The open front end (indicated by arrow 27) permits manual access to the keypad. A person using the ATM has the choice whether to view the keypad directly or through the screen 30, since the screen can be moved to the required position by gripping its proximal edge and sliding it backwards over the distal wall or forward towards themselves. The keypad 24 is operated by a person extending their hand through the opening 27, so as to access the keys.

With reference to FIGS. 4 and 5, a second embodiment of the shield, having a screen rigidly fixed to the sidewalls, will now be described. The second embodiment of the shield is similar to the first embodiment, in as much as it comprises a main body 11 that has two opposing sidewalls 12 and a distal wall 13 that extends therebetween. This invention further includes an upper wall extending between the sidewalls, and defining a screen 30 adapted to overlie a keypad. As described in the first embodiment, any point on the surface of the screen appears transparent when viewed from within a viewing range shaped as an inverted 20° pyramid having a square base. The screen defines a large entrance 28 at a proximal side 33 to permit manual access to the keypad. A fixed shield like this could be slidably mounted as a whole around the keypad so that the keypad operator has the option of positioning it over the keypad or retracted from the keypad. Such a version would require guide means on the under side of each flange for slidably mounting the shield to correspondingly arranged guide means on the surface surrounding the keypad.

Referring now to FIG. 5, a ridge is formed in the upper wall of the main body extending parallel to the sidewalls and midway therebetween. The ridge defines two substantially symmetric surfaces, azimuthally angled at 10°.

With reference to FIGS. 6 and 7, a third embodiment of the invention, for use with chip and pin units, will now be described briefly.

The third embodiment of the shield comprises two opposing side plates 40, mounted to the side of a chip and pin keypad unit 41, for slidably supporting a screen 42. Each side plate 40 is generally arcuate and is formed such that the arcuate upper edge 45 is substantially longer than the arcuate lower edge 46. The side plates are sloped, such that the distance between the upper edges is greater than the distance between the lower edges, thus allowing large hands to access a keypad 48, which in generally is quite small.

A screen 42 having a proximal edge 51 near the keypad operator, a distal edge 52 remote from the keypad operator and two substantially parallel extending side edges (not visible), is provided between the two side plates 40. The two side edges of the screen 42 slidably locate in channels at the upper edges of side plates 40. The length of each side edge, and therefore the screen 42 itself, is less than the length of each upper edge 45, enabling the screen to be slid from a use position overlying the keypad to a retracted position whereat it does not overlie the keypad.

In use, each side plate 40 is attached to the respective sides of a chip and pin unit 41, and the screen 42 is slidably disposed therebetween. The chip and pin is used in much the same way as the ATM unit described above. The shield should not obstruct insertion of a card into the chip and pin unit, which usually occurs at the top thereof.

1. A shield for overlying a keypad and comprising a main body connectable to the keypad, a screen defined in the main body and overlying the keypad through which screen the keypad may only be viewed by the user of the keypad, the main body further defining an opening through which manual access to the keypad is permitted.

2. A shield as claimed in claim 1, wherein the keypad may only be viewed through the screen from within a range of angles, which range is approximately 20° centred normal to the surface of the screen.

3. A shield as claimed in claim 1, wherein the main body comprises two opposing sidewalls spaced apart laterally, the screen being mounted therebetween.

4. A shield as claimed in claim 3, wherein the main body further comprises a distal wall extending from between the two sidewalls opposite the opening defined for manual access.

5. A shield as claimed in claim 4, wherein the screen is defined within an upper wall extending between the two sidewalls.

6. A shield as claimed in claim 5, wherein the upper wall is formed from an extension of the distal wall.

7. A shield as claimed in claim 1, wherein the screen is slidably located for movement between a use position overlying the keypad, and a retracted position not overlying the keypad.

8. A shield as claimed in claim 1, wherein a lower portion of the main body is suitably arranged to connect to a surface around the keypad.

9. A shield as claimed in claim 8, wherein the main body is attached to a keypad by adhesive, adhesive tape or fasteners.

10. A shield as claimed in claim 1, wherein the shield is adapted to be connected to an ATM.

11. A shield as claimed in claims 1, wherein the shield is adapted to be connected to chip and pin keypad units.

12. A shield as claimed in claim 1, wherein the walls are made from high oil based plastics material.

13. A device incorporating a keypad, and including a shield as claimed in claim 1 arranged over the keypad.
